(19) United States
(12) Patent Application Publication
(10) Pub. No.: US 2022/0075407 A1
(43) Pub. Date: Mar. 10, 2022

(54) MODULAR COMPUTER CASE SHARING MONITOR ASSEMBLING BRACKET WITH POWER SUPPLIER

(71) Applicant: YEN-WEI CHEN, TAOYUAN CITY (TW)

(72) Inventor: YEN-WEI CHEN, TAOYUAN CITY (TW)

(21) Appl. No.: 17/088,904

(22) Filed: Nov. 4, 2020

(30) Foreign Application Priority Data
Sep. 9, 2020 (TW) 109130984

(51) Int. Cl. G06F 1/16; H05K 7/20; H05K 9/00; H05K 5/02; G06F 1/20; G06F 1/18

(52) U.S. Cl. CPC G06F 1/1603; H05K 7/20136; G06F 1/189; H05K 5/0234; G06F 1/20; H05K 9/0009

(57) ABSTRACT

A modular computer case includes a horizontal computer case, a case cover arranged on the opening of the computer case, forming an air exchange system on the case cover; an assembling bracket kit, forming a modular base with the case cover; a predetermined monitor which can be installed on the computer case to form a modular computer case sharing monitor assembling bracket with power supplier, and the front section of the case cover has multiple air suction holes for sucking in the external air and exhausting through the heat dissipation through holes arranged at the rear section of the case cover, so as to form a high-speed cooling ventilation system.

### BACKGROUND OF THE INVENTION

### 1. Field of the Invention

The invention relates to a modular computer case, especially to one that provides consumer more custom options, it can be combined with the monitor in to one piece and be modular, and sharing the assemble bracket of the monitor with the power supplier to achieve having a modular computer case with high-speed cooling ventilation system.

### 2. Description of the Related Art

FIG. 1 illustrates a horizontal computer 230 having the monitor 210 on the top, FIG. 1 illustrates a vertical computer 240 with the monitor 210 arranged separately; both of them are having computer and monitor separately, so they occupy more space, and the tangled and exposed connection wire will affect the appearance.

In order to achieve the purpose of reduce the size of desktop computer, AIO computer (All In One) is appeared; as FIG. 3 as showing, the power supplier, motherboard, hard disk, graphics card and other components are all assembled in the housing 220 that arranged at the rear side of the monitor 210; FIG. 4 illustrates a Taiwan Patent No. M369601 which having the monitor 210 arranged at the front side of the support mechanism 250, the support mechanism 250 includes a base 251 and a support bracket 252 connected with the base 251, and the power supplier, motherboard, hard disk, graphics card and other components are all assembled in support bracket 252; both computers above mentioned are AIO type, since their size is reduced, they are favored by many users; however, the space inside the AIO computer is too small for heat dissipation, so the continuous accumulation of heat will greatly reduce the life of related parts, so the heat dissipation problem forms a fatal flaws to AIO computers.

Moreover, since the development trend of computer computing frequency getting higher and higher, facing the application of high level interface, the AIO computer cannot use the transfer method, and the interface such as USB3.1 and Thunderbolt provided by the mainboard I/O port are set in a place within the user's reach, further resulting in having the problem that high level USB3.1 is not convenience to used. Also, PIO computer (Part In One) allow the user assemble the computer into one piece by himself, it allows the user to choose the graphics card, CPU, hard disc, and etc., to fulfill the requirement of different user, the PIO computer is having the monitor installed with the computer case into one piece.

Also, the computing performance and level of computer parts are proportional to power consumption, the only way to solve the heat dissipation problem is by air changing, in order to achieve making computer case having high power consumption computer units combine with the monitor, and having more custom option, the present invention intends to solve below problems:

1. The vertical computer has the disadvantage that no matter how small the size is, there is always a space be taken for placing computer on the desk.

2. The horizontal computer does not have the mechanism for hanging the monitor, so three main heat resource units, the power supplier, the main board and the graphics card, are arranged inside the computer case, as Patent No. Cn210534649 U showing, there is no other space for installing larger fan, the heat dissipate way is limited by the small fans installed on above mention three units, so when the outer air is suck in the case will create a backpressure and can only dissipate the heat slowly like stirring the air, resulting in extremely bad heat dissipate efficiency; moreover, the air suction holes do not have any protection, if the air suction holes are too big, foreign objects may get into the case and damage components, and there are also concerns about electromagnetic waves (EMI/EMC) leakage and the problem that the monitor may easily get tip over.

3. The all-in-one machine using the monitor frame as the case with non-modular market components, AIO, and the one using modular market component, PIO, both of them have to installed aforementioned three main heat resource unit together into the case, so the heat dissipation problem is worse than the horizontal computer; This type of computer has the problem of low power consumption level, but also because of the monitor size, width ratio, curved surface, and whether it supports 3D features, these users' demand options are all limited, which completely violates the individualized demands and propositions of personal computers, so the sales of AIO and PIO have declined year by year, when NUC computer is released which, since it only has a size of a lunch box with lower power consumption.

4. The horizontal computer case combined with the monitor assembling bracket, as Patent No. CN 210534649 U showing, the cooling fan in the all-in-one computer case can only suck in external air from the ventilation holes on the main cover plate to slowly stir and dissipate heat. Therefore, the residual pressure of the fan is too low to use the side ventilation holes, in addition, there are the problems of foreign objects falling into the case and external radiation that harmful to the human body. Therefore, this all-in-one computer must use a power supplier that cannot support high power consumption, output voltage DC 12V and output current 10 A, it is also specifically stated that the all-in-one computer does not have a graphics card expansion slot, so the monitor assembly bracket is randomly set on the back of the computer with a first threading hole, the first threading hole has six screw holes for fixing the metal connection bracket around the threading hole, and it has not solved the tipping backward problem of all-in-one computer.

5. Four types of computers above mentioned, including computer with graphics card expansion slot, have not considered the problem that cannot be overcome by the development of high-frequency technology, and can no longer use the transfer of the USB3.0 in low-speed interface, and setting the mainboard I/O ports and Thunderbolt at the user's reachable location, resulting in the disadvantage that the use of high-speed interfaces is not as convenient as low-speed interfaces, which hinders the development and business opportunities of computer peripheral products.

6. Thus, the present invention seeks to improve the methods and thought of designing and manufacturing computer case to solve the problems of AIO computer made by the conventional technology, and further make the monitor frame as a PIO computer case, and overcome the problems that happens on personalized arrangement, heat dissipation effect, and miniaturization purpose.

### SUMMARY OF THE INVENTION

It is a primary objective of the present invention to provide a modular computer case sharing monitor assembling bracket with power supplier, assemble all component with the monitor to form an all-in-one computer, and install the power supplier outside the computer case for miniaturization the space that computer taken on the desk and extends the life of components.

In order to achieve the above objectives, the present invention including: a computer case, which is a horizontal PC case having an upward opening, inside the opening has a containing space for installing related computer units, the rear side of the computer case has a first opening for installing a predetermined I/O port of a display card, at the other side of the computer case has a second opening for installing a predetermined I/O port of a mainboard; a case cover set at the opening of the computer case, the case cover has multiple air suction holes arranged at the front section; the rear section of the case cover has at least an upward heat dissipation through hole for installing at least a predetermined cooling fan or a water cooling radiator with fan, the multiple air suction holes allow the predetermined fan inside the computer case to suck in the outside air and then go through the heat dissipation through holes and to form a high-speed cooling ventilation system, and a mounting hole for arranging a predetermined power supplier; an assembling bracket kit having an upright structure, a power supplier assembling positioning kit arranged at the outer periphery of the upright structure, and a monitor assembling positioning kit, wherein the power supplier assembling positioning kit and the monitor assembling positioning kit are arranged at the outer periphery of the upright structure, and the bottom end of the upright structure is secured on the case cover, the monitor assembling positioning kit further has a junction at the front side for making the case cover and the assembling bracket kit composing a modular base; and the modular base can be installed quickly on the computer case to form a modular computer case sharing monitor assembling bracket with power supplier.

Also, the related computer units can be contained inside the computer case including: a mainboard, a first suction fan, a display card, and a second suction fan which combined on the display card, and inside the case cover can arrange a PCIe slot for installing a PCIe extension cable, the PCIe slot is arranged correspondingly to the display card and the mainboard.

Also, the heat dissipation through holes is for installing a predetermined cooling fan, using the first suction fan and second suction fan to suck in the outside cold air and then exhaust the heat inside the computer case by the predetermined cooling fan, the predetermined cooling fan includes a water cooling radiator.

Also, the composition of the air suction holes includes: at least an air suction port arranged at the front section of the case cover, and on the any side of the air suction port has multiple interval plates; a first-type cover mask having multiple first hollow holes arranged at the front section of the case cover for making interval plates to be partial exposed, and the first-type cover mask is covered on the air suction port and the interval plates of the case cover for making the air suction port and the interval plates form multiples passages or through holes that avoid foreign objects and electromagnetic wave leakage by sucking in the outside air from lateral side.

Also, the air suction port at the front section of the case cover and the heat dissipation through hole at the rear section further include a second-type cover mask with larger area, the second-type cover mask not only has the first hollow holes arranged at the first-type cover mask but also has a second hollow hole that make the mounting holes and the positioning hole to be exposed at the rear section of the case cover, the second-type cover mask covers the air suction port and part of the interval plates, between each of the interval plates remain the air suction holes for exchanging air; the second-type cover mask has multiple meshes arranged correspondingly to the arrangement of the heat dissipation through holes, and the predetermined cooling fan can be arranged below the heat dissipation through holes and not be protruding out of the top surface of the case cover.

Also, the structure of the air suction holes is multiple air suction holes formed in one piece at the front section of the case cover.

Also, the mounting holes of the computer case is for installing with the bottom of the power supplier, using the power supplier assembling positioning kit to secure the predetermined power supplier at the lateral side of the upright structure to let the exhaust mesh which arranged on the top of the power supplier be installed upward and be exposed outside the computer case, and the mounting holes can let the predetermined power supply cable of the power supplier to set through and further make the computer units inside the computer case to be electrically connected, and the case cover has a positioning hole corresponds to the bottom of the upright structure to secure the upright structure on the case cover by a positioning unit.

Also, the shape of the upright structure includes column, bar, and plate.

Also, the front side of the junction of the monitor assembling positioning kit is for installing a predetermined monitor, and the monitor assembling positioning kit further includes a pivot and an adjustment unit in order to adjust the height of the monitor assembling positioning kit according to the upright structure and to adjust the angle of the predetermined monitor according the monitor assembling positioning kit.

Also, at the rear side of the case cover and the computer case has a pivot mechanism for making the case cover able to be open for assembling and maintaining task inside the computer case.

With the features disclosed above, the present invention has below benefits: having a high-speed cooling ventilation system, and installing the power supplier outside the PIO computer case for miniaturization the space that computer taken on the desk and extends the life of components.

### BRIEF DESCRIPTION OF THE DRAWINGS

FIG. 1 is a schematic diagram illustrating arrangement of the conventional horizontal computer;

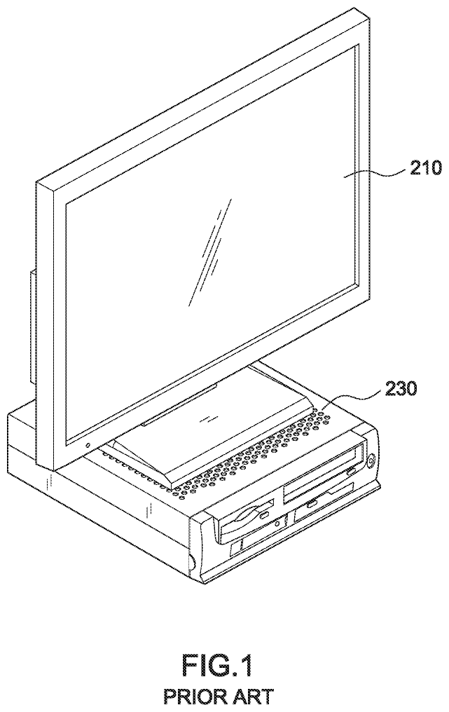

FIG. 2 is a schematic diagram illustrating arrangement of the conventional vertical computer;

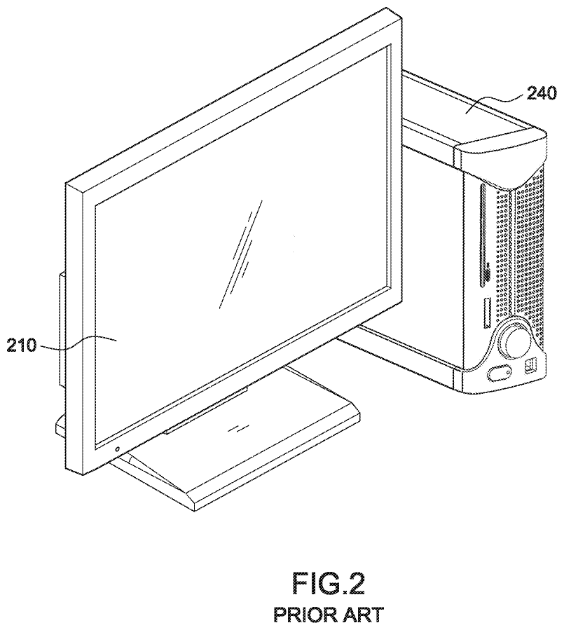

FIG. 3 is a schematic diagram illustrating arrangement of an all-in-one computer;

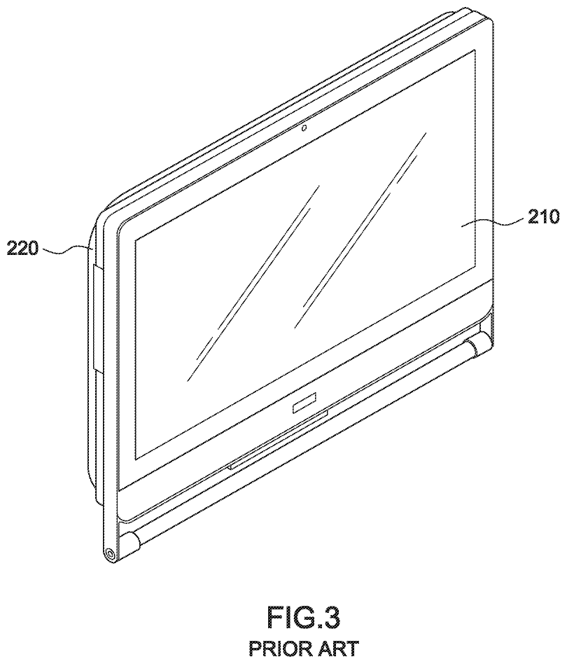

FIG. 4 is a schematic diagram illustrating arrangement of another type all-in-one computer;

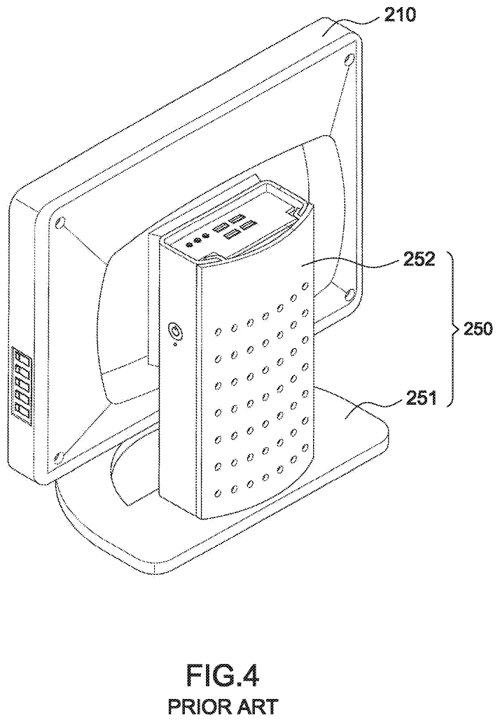

FIG. 5 is an exploded perspective view of the present invention;

FIG. 6A is a perspective view of the modular base of the present invention without the first-type cover mask;

FIG. 6B is a perspective view of the modular base of the present invention with the first-type cover mask;

FIG. 6C is an exploded perspective view of the modular base and the first-type cover mask of the present invention;

FIG. 6D is an assembly perspective view of the modular base and the first-type cover mask of the present invention;

FIG. 6E is a perspective view of the air suction holes of the present invention which forming into one piece at the front section of the case cover;

FIG. 7 is a perspective view of the first assemble step of the present invention;

FIG. 8 is a perspective view of the second assemble step of the present invention;

FIG. 9 is a perspective view of the third assemble step of the present invention;

FIG. 10 is another assembly perspective view of the present invention;

FIG. 11 is a schematic diagram illustrating the heat dissipation of the present invention;

FIG. 12 is a schematic diagram illustrating the case cover of the present invention while opened;

FIG. 13 is a schematic diagram illustrating the connect units of the monitor during adjusting;

FIG. 14 is a structure perspective view of the bracket kit in another embodiment of the present invention;

FIG. 15 is a perspective view of the cooling fan in another embodiment of the present invention.

### DETAILED DESCRIPTION OF THE PREFERRED EMBODIMENT

For better understanding of present invention, I provide the embodiment and drawing enclosed for detailed description. Those who skilled in the art can understand purpose, the feature and benefit of the present invention from the contents disclosed in this specification. Kindly noted that the present invention can be implemented or applied through other different specific embodiments and based on different viewpoints various details in this specification can be various changed without departing from the spirit of the present invention. In addition, the drawings attached to the present invention are merely a schematic illustration and they are not depicted in actual dimensions. The following embodiments will further describe the related technical content of the present invention in detail, but the disclosed content is not intended to limit the technical scope of the present invention.

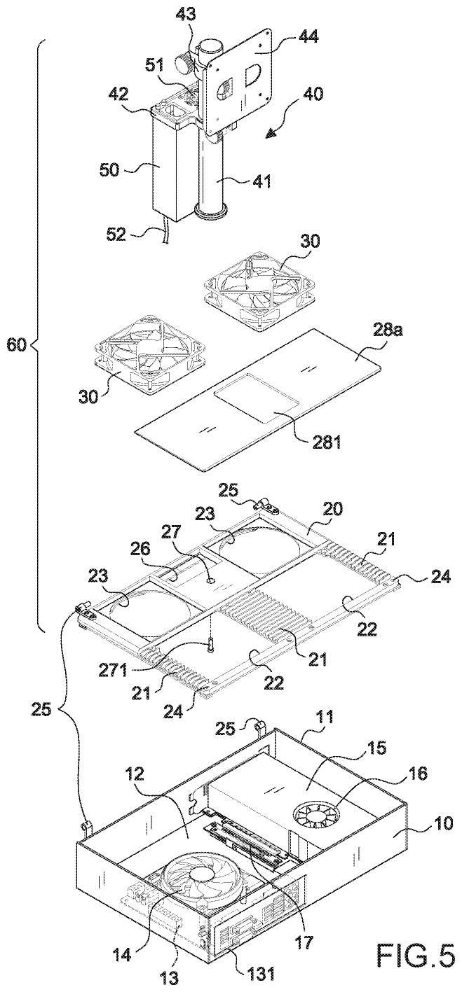

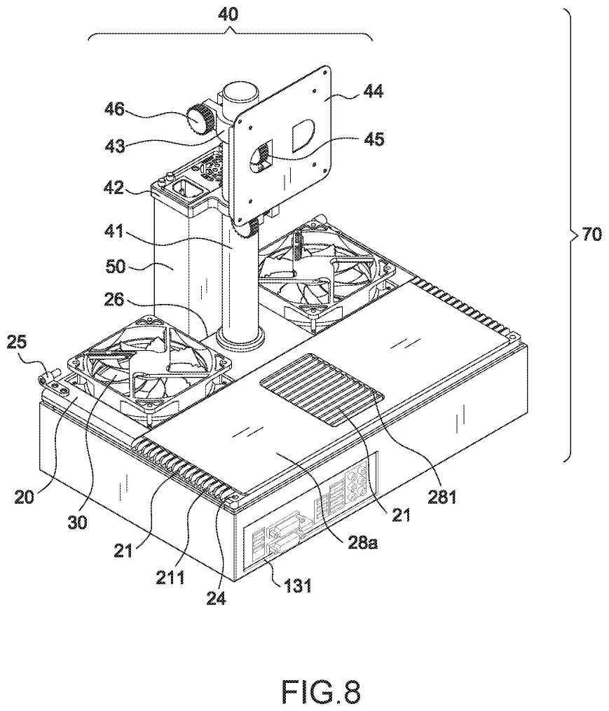

Referring to FIGS. 5-15, the present invention is a modular computer case sharing monitor assembling bracket with power supplier, comprising: a computer case 10, which is a horizontal PC case having an upward opening 11, inside the opening 11 has a containing space 12 for installing related computer units, in this embodiment, the related computer units can be contained inside the computer case 10 including: a mainboard 13, a first suction fan 14, a display card 15, a second suction fan 16 which combined on the display card 15, and etc.

A case cover 20 set at the opening 11 of the computer case 10, the case cover 20 has multiple air suction holes 211 arranged at the front section; the rear section of the case cover 20 has an upward heat dissipation through hole 23 for installing at least a predetermined cooling fan 30 or a water cooling radiator 31 with fan, the multiple air suction holes 211 allow the predetermined fan inside the computer case 10 to suck in the outside air and then go through the heat dissipation through holes 23 and to form a high-speed cooling ventilation system, and a mounting hole 26 for arranging a predetermined power supplier 50.

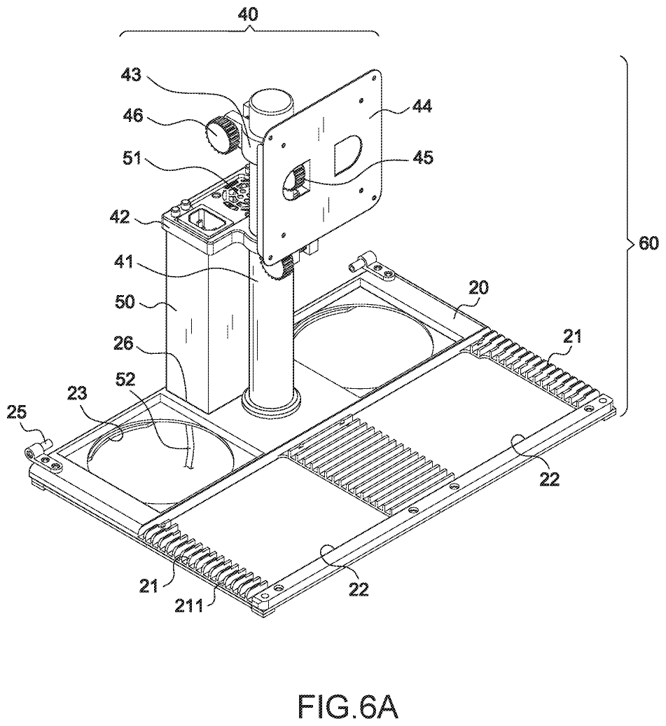

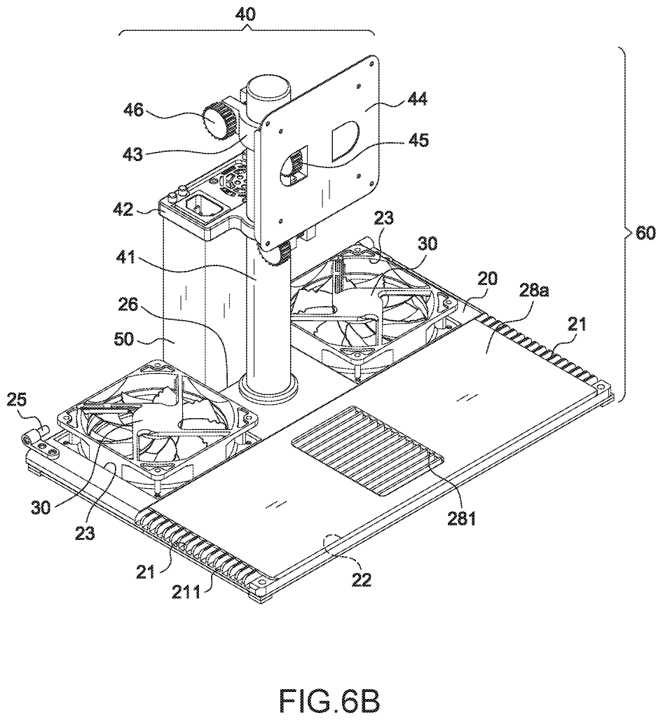

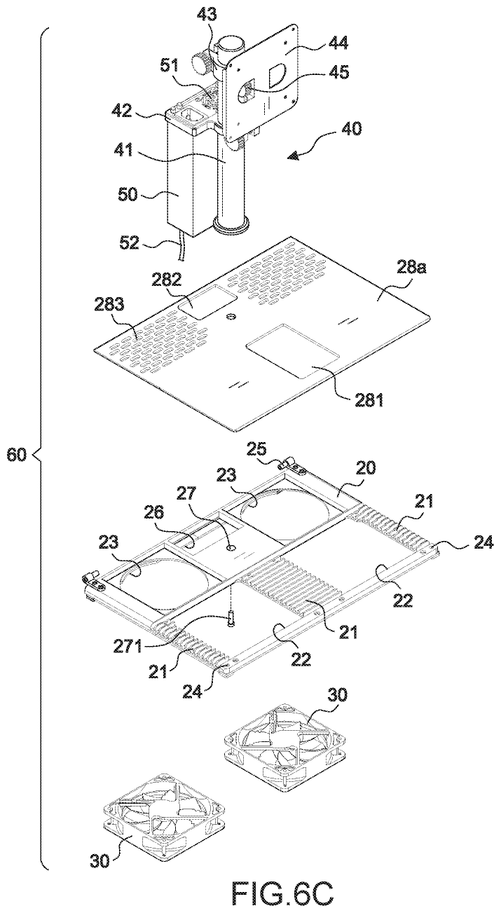

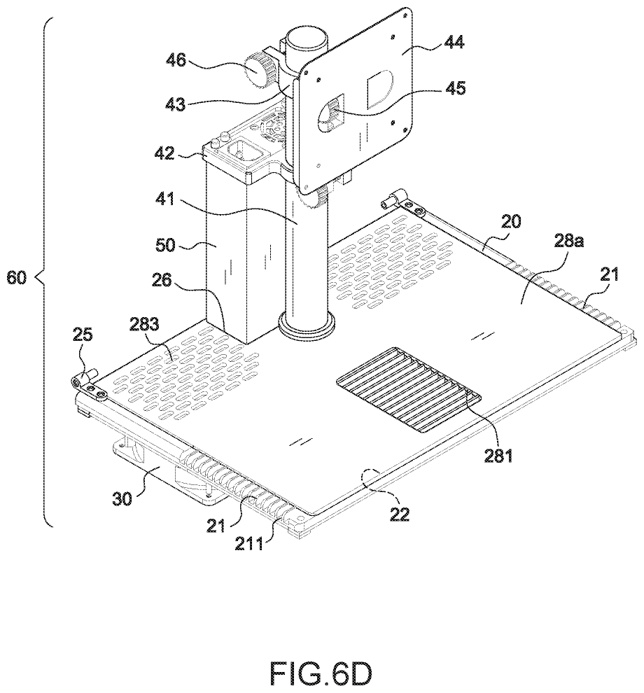

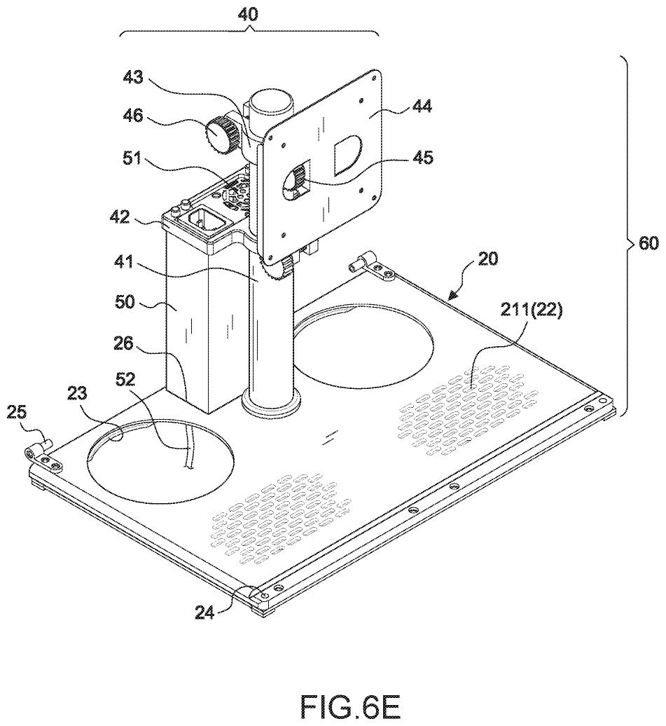

Referring to FIGS. 6A-6B, in this embodiment, the composition of the air suction holes 211 includes: at least an air suction port 22 arranged at the front section of the case cover 20, and on the any side of the air suction port 22 has multiple interval plates 21, like a shape of fish scales or fence; a first-type cover mask 28a having multiple first hollow holes 281 arranged at the front section of the case cover 20 for making interval plates 21 to be partial exposed, and the first-type cover mask 28a is covered on the air suction port 22 and the interval plates 21 of the case cover 20 for making the air suction port 22 and the interval plates 21 form multiples passages or through holes that avoid foreign objects and electromagnetic wave leakage by sucking in the outside air from lateral side.

Referring to FIGS. 6C-6D, in this embodiment, the air suction port 22 at the front section of the case cover 20 and the heat dissipation through hole 23 at the rear section further include a second-type cover mask 28b with larger area, the second-type cover mask 28b not only has the first hollow holes 281 arranged at the first-type cover mask 28a but also has a second hollow hole 282 that make the mounting holes 26 and the positioning hole 27 to be exposed at the rear section of the case cover 20, the second-type cover mask 28b covers the air suction port 22 and part of the interval plates 21, between each of the interval plates 21 remain the air suction holes 211 for exchanging air; the second-type cover mask 28b has multiple meshes 283 arranged correspondingly to the arrangement of the heat dissipation through holes 23, and the predetermined cooling fan 30 can be arranged below the heat dissipation through holes 23 and not be protruding out of the top surface of the case cover 20.

Referring to FIG. 6E, in another embodiment, the structure of the air suction holes 211 is multiple air suction holes 211 formed in one piece at the front section of the case cover 20, and the quantity of the air suction holes 211 can be different by the requirement; in above embodiment, at place where the air suction port 22 arranged or the place near to the air suction port 22, the air suction holes 211 provide the effect of the air suction passage.

Also, the rear section of the case cover 20 has at least an upward heat dissipation through hole 23 for installing predetermined cooling fan 30 or a water cooling system, and the heat dissipation through hole 23 and the air suction holes 211 further form a high-speed cooling ventilation system. For installing the case cover 20 on the computer case 10, on the four corners of the case cover 20 have screw holes 24, and two corners at the rear section have a pivot mechanism 25 for making the case cover 20 of the computer case 10 enable to be lifted off for assembling and maintaining task inside the computer case 10; the two screw holes 24 of the two corners at the front section can be buckle, not shown in drawing, in order to let the front section of the case cover 20 achieves fast open and lock effect.

An assembling bracket kit 40 having an upright structure 41, a power supplier assembling positioning kit 42 arranged at the outer periphery of the upright structure 41, and a monitor assembling positioning kit 43, wherein the power supplier assembling positioning kit 42 and the monitor assembling positioning kit 43 are arranged at the outer periphery of the upright structure 41, and the bottom end of the upright structure 41 is secured on the case cover 20, the monitor assembling positioning kit 43 further has a junction 44; in this embodiment, the shape of the upright structure 41 includes column, bar, and plate, but the present invention is not limited to such application.

In this embodiment, the mounting holes 26 of the case cover 20 is for installing with the bottom of a predetermined power supplier 50, using the power supplier assembling positioning kit 42 to secure the predetermined power supplier 50 at the lateral side of the upright structure 41 to let the exhaust mesh 51 which arranged on the top of the power supplier 50 be installed upward and be exposed outside the computer case 10, and the mounting holes 26 can let the predetermined power supply cable 52 of the power supplier 50 to set through and further make the computer units inside the computer case 10 to be electrically connected, and the case cover 20 has a positioning hole 27 corresponds to the bottom of the upright structure 41 to secure the upright structure 41 on the case cover 20 by a positioning unit, and make the power supplier 50 be arranged at the rear side of the assembling bracket kit 40 and outside the computer case 10, which also means the power supplier 50 is exposed outside the computer case 10 for making the case cover 20 and the assembling bracket kit 40 form a modular base 60; and the modular base 60 make the case cover 20 to be convenient installed on the computer case 10; and the assembling bracket kit 40 can install the monitor 80 quickly to form a modular computer case 70 sharing monitor assembling bracket with power supplier 50.

Also, at least a predetermined cooling fan 30 which can be arranged on the heat dissipation through hole 23, and using the first suction fan 14 and second suction fan 16 to suck in the outside cold air A1 and then exhaust the heat inside the computer case 10 by the predetermined cooling fan 30, and the type of the predetermined cooling fan 30 is not limited.

In this embodiment, the second-type cover mask 28b can be a metal or transparent glass plate; But the present invention is not limited to such application. The following embodiment is based on the first-type cover mask 28.

The first-type cover mask 28 made of metal or other antimagnetic material is for covering on the air suction port 22 of the case cover 20 to prevent the outward radiation of the magnetic wave EMI/EMC of the computer units and avoid the foreign objects form getting in the computer case 10, and the first-type cover mask 28 can be temporally removed while necessary.

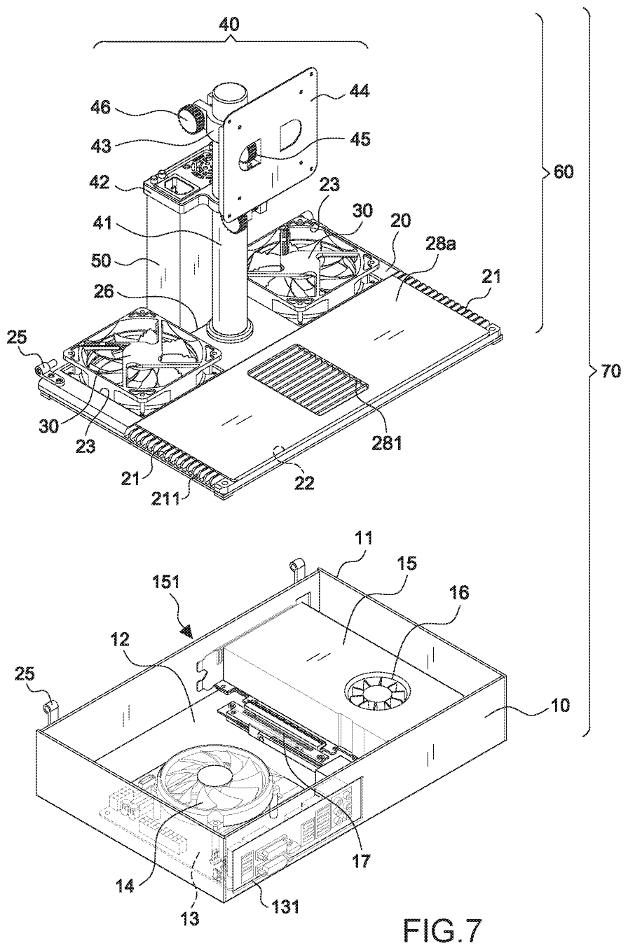

FIGS. 7-10 are illustrating the steps for assembling a modular computer case 70 sharing monitor assembling bracket with power supplier; First, securing the bottom end of the upright structure 41 at the positioning hole 27 of the case cover 20 by positioning units 271; then, securing the top end of the power supplier 50 with the power supplier assembling positioning kit 42, and let the predetermined power supply cable 52 set through the mounting holes 26 of the case cover 20 and let the bottom end stands on the case cover 20, and further let it be arranged at the rear side of the assembling bracket kit 40; then, set the monitor assembling positioning kit 43 at the outer periphery of the upright structure 41 and the above the power supplier assembling positioning kit 42, and let the junction 44 toward the front side of the assembling bracket kit 40, as FIG. 6A showing; then, choosing the main board 13, the first suction fan 14, the display card 15 and the second suction fan 16 which combined on the display card 15 installed inside the containing space 12 of the computer case 10 of the horizontal computer.

In this embodiment, a first opening 151 for installing a predetermined I/O port of a display card 15 is arranged at the rear side of the computer case 10; a second opening 131 for installing a predetermined I/O port of a mainboard 13 is arranged at the front or left or right side of the computer case 10; and inside the case cover 20 further has a PCIe slot 17 for installing a PCIe extension cable, the PCIe slot 17 is arranged correspondingly to the display card 15 and the mainboard 13. Therefore, the present invention can set the mainboard 13 I/O ports at the user's reachable location, so the user can directly use the USB 3.0, USB3.1, USB 4 and Thunderbolt of the mainboard 13.

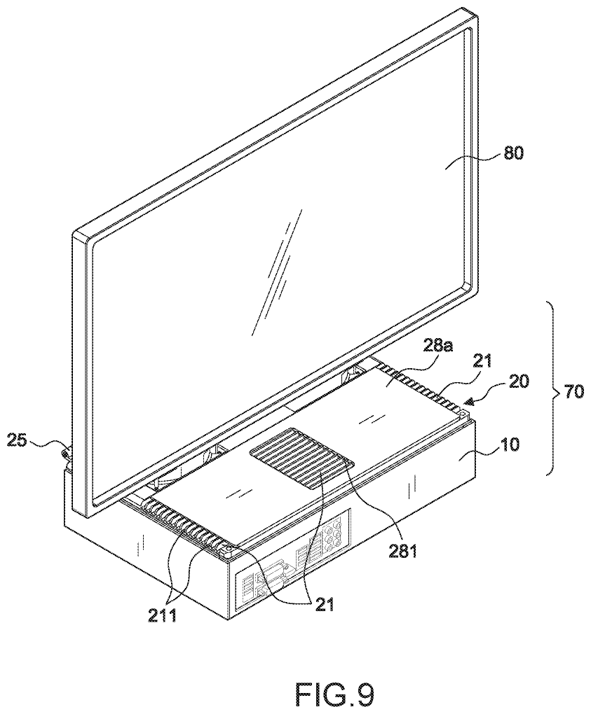

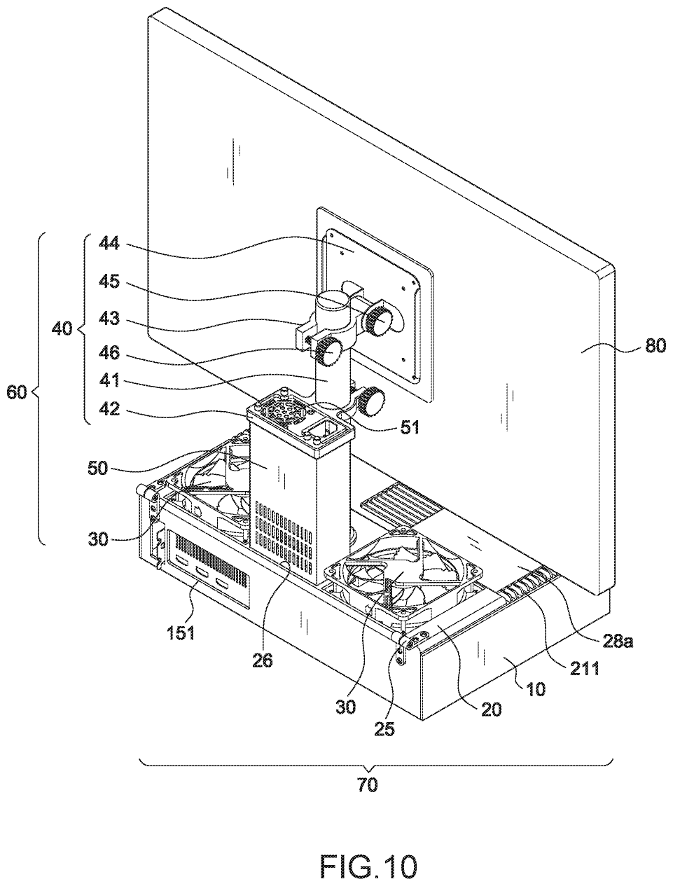

Also, the present invention can choose to arrange two cooling fan 30 above the two heat dissipation through holes 23 of the rear side of the case cover 20, and cover the first-type cover mask 28a on the air suction port 22 of the case cover 20, as FIG. 7 showing; then, arrange pivot mechanisms 25 with the hinge at the two corner of the rear section of the case cover 20, and arrange securing mechanisms with the screw hole 24 at the two corner of the front section of the case cover 20 making the case cover 20 be arranged on the computer case 10, as FIG. showing; moreover, installing the monitor 80 at the front side of the junction 44 of the monitor assembling positioning kit 43 will complete a modular computer case sharing monitor assembling bracket with power supplier, as FIGS. 9-10 showing.

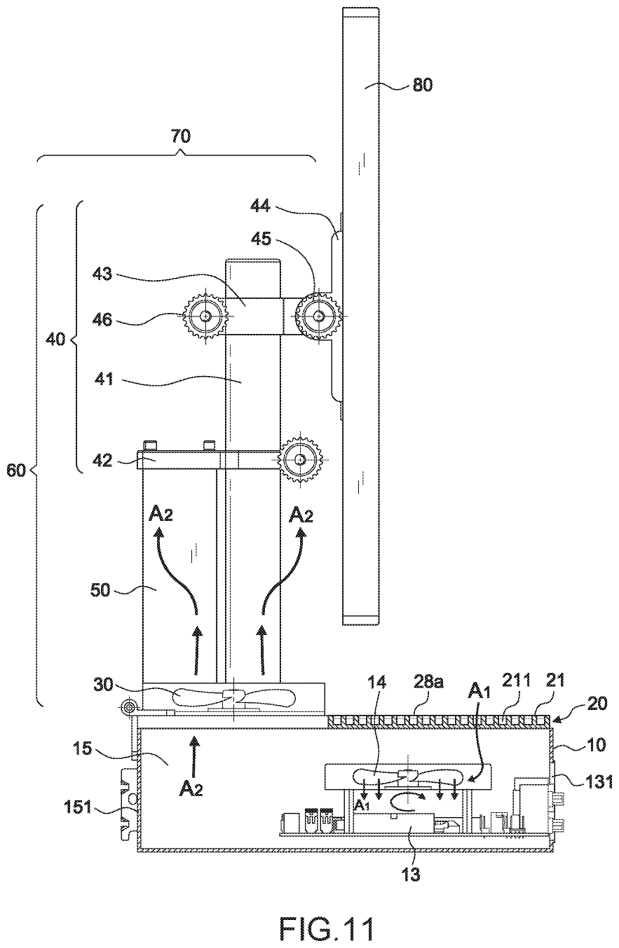

FIG. 11 is a schematic diagram illustrating the heat dissipation of the present invention; wherein, the cold air A1 is sucked into the computer case 10 from the two air suction ports 22 which arranged at the front side of the case cover 20, then by stirring of the first suction fan 14 and the second suction fan 16 will exchange heat with the main board 13 and display card 15, and the heat A2 will be exhausted outside the computer case 10 by the cooling fan 30 through the heat dissipation through hole 23 of the case cover 20.

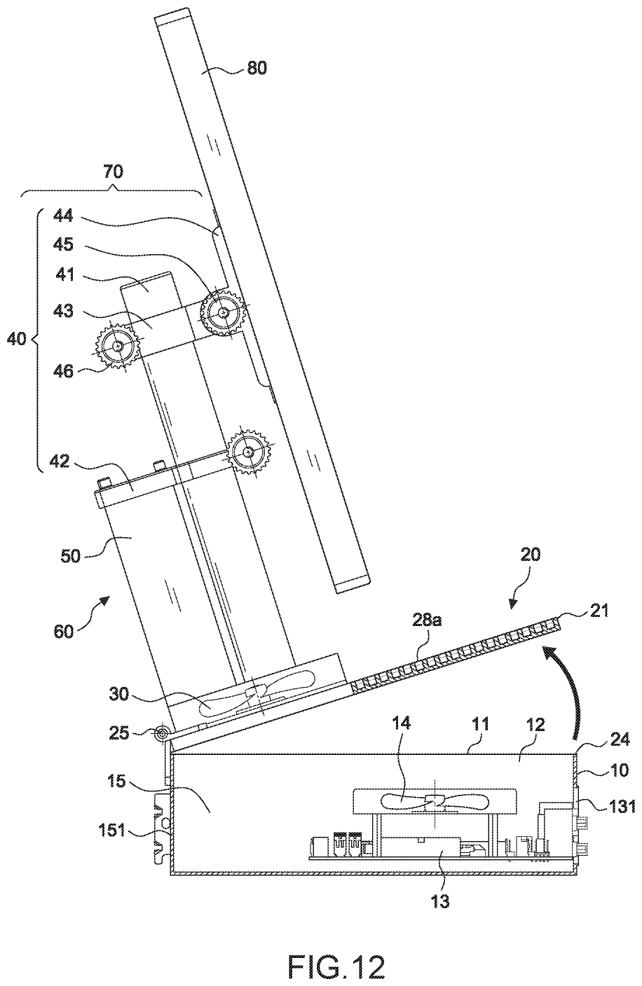

As FIG. 12 showing, since the two corner of the rear section of the case cover 20 have the pivot mechanisms 25 with hinge, and the two corner of the front section of the computer case 10 have securing mechanisms with the screw hole 24 or other devices that can have quick fastening function, the case cover 20 can be lifted off with the whole assembling bracket kit 40 that arranged with the power supplier 50 and the monitor 80, so the user does not need to remove any device for doing the maintenance task inside the computer case 10.

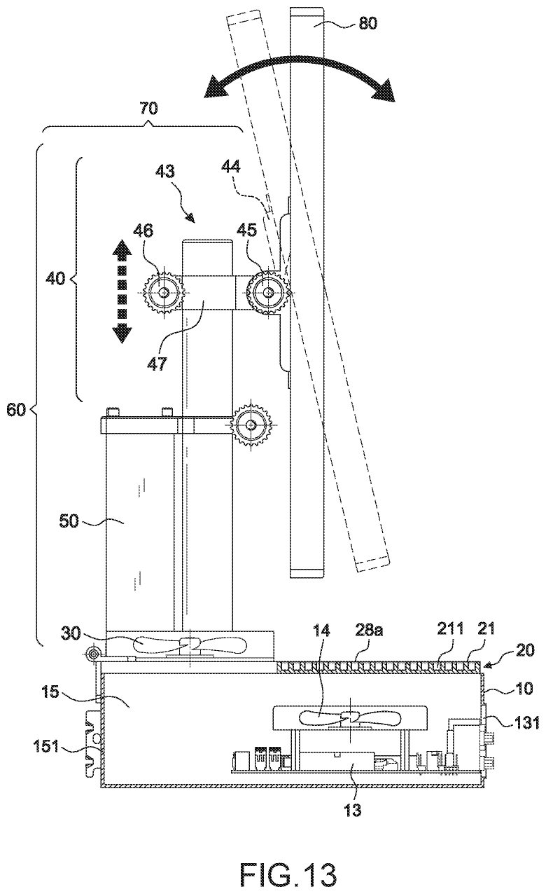

The monitor assembling positioning kit 43 of the present invention has adjustment function, as FIG. 13 showing; wherein the connecting unit of the monitor 80 has a pivot 45 and an adjustment unit 46, the adjustment unit 46 can include but not limited: a bolt with rotate button, the counterclockwise rotation of the adjustment unit 46 loosen the clamping rod 47 holding to the upright structure 41, and the clockwise rotation of the adjustment unit 46 fasten the clamping rod 47 holding to the upright structure 41, therefore, by the rotation of the adjustment unit 46 can adjust the position of the monitor assembling positioning kit 43 corresponding to the upright structure 41, and further achieve the purpose of adjusting the height of the monitor 80; the pivot 45 also has a bolt with rotate button, loosen the rotate bolt can rotate the pivot 45 with the junction 44 can achieve the purpose of adjusting the elevation angle adjustment of the monitor 80.

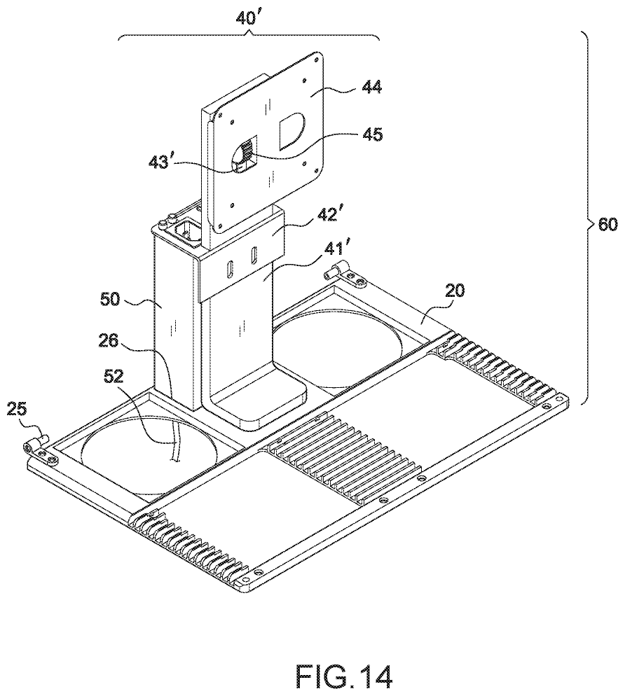

FIG. 14 is illustrating structure of the assembling bracket kit 40′ in another embodiment, the same unit with the above embodiment is marked with same number, the differences are: the upright structure 41′ is rectangle or section of the rectangle, and the power supplier assembling positioning kit 42′ and the monitor assembling positioning kit 43′ coordinate with the section of the upright structure 41′ being arranged at the outer periphery of the upright structure 41′, and the monitor assembling positioning kit 43′ can also adjust the height of the monitor 80 corresponding to the upright structure 41′; and the junction 44 and the pivot 45 is the same. In this embodiment, the modular base 60 compose by the assembling bracket kit 40′ has the same feature to the above embodiment.

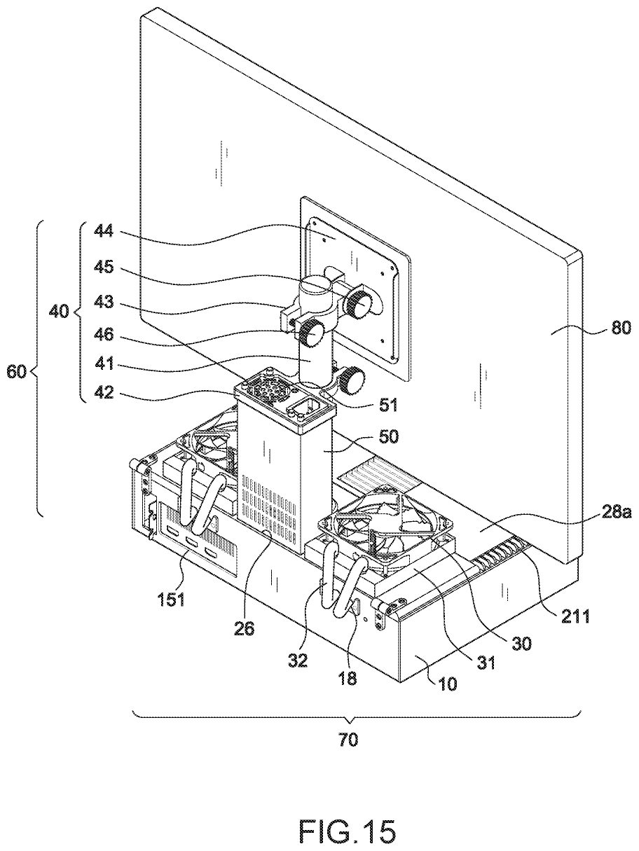

FIG. 15 is a perspective view of the cooling fan 30 in another embodiment, the cooling fan 30 includes a water cooling radiator 31 and a water cooling pipe 32, and the rear side of the computer case 10 has a hard tube water cooling device 18; The water cooling radiator 31 in this embodiment has better heat dissipation effect than the above embodiment.

With the features disclosed above, the present invention has below improved effect:

1. The present invention can choose the display card 15, the mainboard 13 and the first suction fan 14 to be arranged inside the computer case 10 by requirement, above them is a case cover 20 with predetermined cooling fan 30 and the interval plate 21, via the air suction hole 211 suck in the external air and go through the heat dissipation through hole 23 of the rear section of the case cover 20 to form a high-speed cooling ventilation system; and secure the assembling bracket kit 40 of the power supplier 50 and the monitor 80 on the case cover 20 for forming an all-in-one computer with a predetermined monitor 80 and related units, and arranged the predetermined power supplier 50 outside the computer case 10 can avoid the heat dissipation problems, so the all-in-one computer has the benefits of reducing the space that computer taken on the desk and extending the life of components.

2. The present invention not only completely separate the predetermined monitor 80 and the power supplier 50 which are the main heat source, but also has a computer case 10 that can exchange air, only two main heat source main board 13 and display card 15 is left inside, so the heat dissipating speed and effect are better that conventional technique.

3. The present invention can set the mainboard 13 I/O ports at the user's reachable location, so the user can directly use the USB 3.0, USB3.1, USB 4 and Thunderbolt of the mainboard 13, so as to have the effect of expanding hardware conveniently.

4. At the rear side of the case cover 20 and the computer case has a pivot mechanism 25, the user only needs to unlock the locking mechanism of the front side of the case cover 20 and the computer case 10, then the case cover 20 is able to be open together with the power supplier 50 and the predetermined monitor 80 which installed with assembling bracket kit 40, so the user does not need to remove any device to do assembling and maintaining task inside the computer case.

Although particular embodiments of the invention have been described in detail for purposes of illustration, various modifications and enhancements may be made without departing from the spirit and scope of the invention. Accordingly, the invention is not to be limited except as by the appended claims.

What is claimed is:

1. A modular computer case sharing monitor assembling bracket with power supplier, comprising:
a computer case, which is a horizontal PC case having an upward opening, inside the opening has a containing space for installing related computer units, the rear side of the computer case has a first opening for installing a predetermined I/O port of a display card, at the other side of the computer case has a second opening for installing a predetermined I/O port of a mainboard;
a case cover set at the opening of the computer case, the case cover has multiple air suction holes arranged at the front section; the rear section of the case cover has at least an upward heat dissipation through hole for installing at least a predetermined cooling fan or a water cooling radiator with fan, the multiple air suction holes allow the predetermined fan inside the computer case to suck in the outside air and then go through the heat dissipation through holes and to form a high-speed cooling ventilation system, and a mounting hole for arranging a predetermined power supplier;
an assembling bracket kit having an upright structure, a power supplier assembling positioning kit arranged at the outer periphery of the upright structure, and a monitor assembling positioning kit, wherein the power supplier assembling positioning kit and the monitor assembling positioning kit are arranged at the outer periphery of the upright structure, and the bottom end of the upright structure is secured on the case cover, the monitor assembling positioning kit further has a junction at the front side for making the case cover and the assembling bracket kit composing a modular base 60 and
the modular base can be installed quickly on the computer case to form a modular computer case sharing monitor assembling bracket with power supplier.

2. The modular computer case sharing monitor assembling bracket with power supplier as claimed in claim 1, wherein the related computer units that can be contained inside the computer case including: a mainboard, a first suction fan, a display card, and a second suction fan which combined on the display card, and inside the case cover can arrange a PCIe slot for installing a PCIe extension cable, the PCIe slot is arranged correspondingly to the display card and the mainboard.

3. The modular computer case sharing monitor assembling bracket with power supplier as claimed in claim 2, wherein the heat dissipation through holes is for installing a predetermined cooling fan, using the first suction fan and second suction fan to suck in the outside cold air and then exhaust the heat inside the computer case by the predetermined cooling fan, and the predetermined cooling fan includes a water cooling radiator.

4. The modular computer case sharing monitor assembling bracket with power supplier as claimed in claim 1, wherein the composition of the air suction holes includes: at least an air suction port arranged at the front section of the case cover, and on the any side of the air suction port has multiple interval plates; a first-type cover mask having multiple first hollow holes arranged at the front section of the case cover for making interval plates to be partial exposed, and the first-type cover mask is covered on the air suction port and the interval plates of the case cover for making the air suction port and the interval plates form multiples passages or through holes that avoid foreign objects and electromagnetic wave leakage by sucking in the outside air from lateral side.

5. The modular computer case sharing monitor assembling bracket with power supplier as claimed in claim 4, wherein the air suction port at the front section of the case cover and the heat dissipation through hole at the rear section further include a second-type cover mask with larger area, the second-type cover mask not only has the first hollow holes arranged at the first-type cover mask but also has a second hollow hole that make the mounting holes and the positioning hole to be exposed at the rear section of the case cover, the second-type cover mask covers the air suction port and part of the interval plates, between each of the interval plates remain the air suction holes for exchanging air; the second-type cover mask has multiple meshes arranged correspondingly to the arrangement of the heat dissipation through holes, and the predetermined cooling fan can be arranged below the heat dissipation through holes and not be protruding out of the top surface of the case cover.

6. The modular computer case sharing monitor assembling bracket with power supplier as claimed in claim 1, wherein the structure of the air suction holes is multiple air suction holes formed in one piece at the front section of the case cover.

7. The modular computer case sharing monitor assembling bracket with power supplier as claimed in claim 1, wherein the mounting holes of the computer case is for installing with the bottom of the power supplier, using the power supplier assembling positioning kit to secure the predetermined power supplier at the lateral side of the upright structure to let the exhaust mesh which arranged on the top of the power supplier be installed upward and be exposed outside the computer case, and the mounting holes can let the predetermined power supply cable of the power supplier to set through and further make the computer units inside the computer case to be electrically connected, and the case cover has a positioning hole corresponds to the bottom of the upright structure to secure the upright structure on the case cover by a positioning unit.

8. The modular computer case sharing monitor assembling bracket with power supplier as claimed in claim 1, wherein the shape of the upright structure includes column, bar, and plate.

9. The modular computer case sharing monitor assembling bracket with power supplier as claimed in claim 1, wherein the front side of the junction of the monitor assembling positioning kit is for installing a predetermined monitor, and the monitor assembling positioning kit further includes a pivot and an adjustment unit in order to adjust the height of the monitor assembling positioning kit according to the upright structure and to adjust the angle of the predetermined monitor according the monitor assembling positioning kit.

10. The modular computer case sharing monitor assembling bracket with power supplier as claimed in claim 1, wherein at the rear side of the case cover and the computer case has a pivot mechanism for making the case cover able to be open for assembling and maintaining task inside the computer case.
